(19) United States
(12) Patent Application Publication
(10) Pub. No.: US 2009/0181492 A1
(43) Pub. Date: Jul. 16, 2009

(54) NANO-CLEAVE A THIN-FILM OF SILICON FOR SOLAR CELL FABRICATION

(76) Inventors: Peter Nunan, Monte Sereno, CA (US); Steven R. Walther, Andover, MA (US); Yuri Erokhin, Georgetown, MA (US)

Correspondence Address: Scott Faber, Esq.;Varian Semiconductor Equipment Associates, Inc, 35 Dory Road, Gloucester, MA, 01930, US

(21) Appl. No.: 12/013,064

(22) Filed: Jan. 11, 2008

(51) Int. Cl. H01L 31/18

(52) U.S. Cl. 438/97; 438/57; 257/E31.045

(57) ABSTRACT

An approach for nano-cleaving a thin-film of silicon for solar cell fabrication is described. In one embodiment, there is a method of forming a substrate for use as a solar cell substrate. In this embodiment, a substrate of silicon is provided and implanted with an ion flux. A non-silicon substrate is attached to the thin-film of silicon to form a solar cell substrate.

### BACKGROUND

This disclosure relates generally to solar cells and more specifically to nano-cleaving a thin-film of silicon for use in fabricating a solar cell.

A typical solar cell has a starting substrate made from silicon, crystalline silicon or polycrystalline silicon. One of the most significant costs of manufacturing a solar cell is the cost associated with the starting substrate itself. In some instances, the cost of a starting substrate made from silicon can constitute up to 70% of the price of a solar cell. Because the processing associated with the starting substrate is relatively simple and inexpensive, there is a desire to reduce the cost of the starting substrate by reducing the amount of silicon used in the substrate to a thin-film. A thin-film starting substrate for a typical solar cell has a thickness that ranges from about 200 microns to about 270 microns. In order for solar energy to be an accepted alternative energy source, costs associated with using solar energy need to decrease to a level that is competitive to non-renewable energy sources. One way to reduce the costs associated with solar energy is to reduce the costs of manufacturing a solar cell. Reducing the thickness of a thin-film starting substrate below current thickness levels would make a significant impact in lowering the costs of a typical solar cell.

### SUMMARY

In a first embodiment, there is a method of forming a substrate for use as a solar cell substrate. In this embodiment, the method comprises providing a substrate of silicon; implanting the silicon substrate with an ion flux; cleaving a thin-film of silicon from the ion implanted silicon substrate; and attaching a non-silicon substrate to the thin-film of silicon to form a solar cell substrate.

In a second embodiment, there is a method of forming a substrate for use as a solar cell substrate. In this embodiment, the method comprises providing a substrate of silicon; implanting the silicon substrate with an ion flux; cleaving a thin-film of silicon from the ion implanted silicon substrate; attaching a non-silicon substrate to the thin-film of silicon to form a solar cell substrate; and post cleave processing of the solar cell substrate.

In a third embodiment, there is a solar cell substrate. In this embodiment, the solar cell substrate comprises a thin-film of ion implanted silicon, wherein the thin-film of ion implanted silicon has a thickness that is less than about five microns. A non-silicon substrate is attached to the thin-film of ion implanted silicon.

In a fourth embodiment, there is a system for forming a solar cell substrate. In this embodiment, the system comprises means for providing a substrate of silicon; means for implanting the silicon substrate with an ion flux; means for cleaving a thin-film of silicon from the ion implanted silicon substrate; and means for attaching a non-silicon substrate to the thin-film of silicon to form a solar cell substrate.

### BRIEF DESCRIPTION OF THE DRAWINGS

FIG. 1 shows a flow chart describing aspects of a method of forming a substrate for use as a solar cell substrate according to one embodiment of this disclosure;

FIG. 2 shows a schematic block diagram of an ion implanter used in an aspect of forming a solar cell substrate according to one embodiment of this disclosure;

FIG. 3 shows a schematic block diagram of a plasma implanter used in an aspect of forming a solar cell substrate according to one embodiment of this disclosure; and

FIG. 4 is a cross-sectional schematic diagram of a solar cell substrate fabricated according to one embodiment of this disclosure.

### DETAILED DESCRIPTION

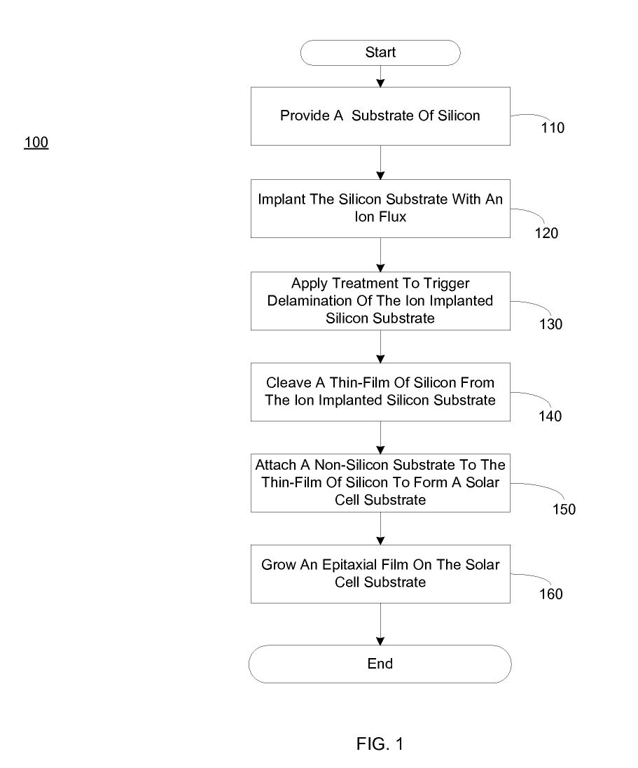

FIG. 1 shows a flow chart describing aspects of a method 100 of forming a starting substrate for use as a solar cell substrate according to one embodiment of this disclosure. The method 100 of FIG. 1 begins at 110 where a substrate of silicon is provided. In one embodiment the silicon substrate can be a monocrystalline silicon or polycrystalline silicon. Those skilled in the art will recognize that other types of silicon can be used such as amorphous silicon. In one embodiment, the silicon substrate can have a thickness that is greater than 150 microns with a preferred range of about 150 microns to about 270 microns.

An ion flux is implanted into the silicon substrate at 120. Ion implantation of the ion flux can occur via an ion implanter (e.g., a conventional beamline implanter, flood implanter, etc.), or a plasma implanter. Basically, any tool that can produce an energetic and strong enough ion flux can be used in the formation of a starting substrate for a solar cell in accordance with the principles of this disclosure. Below are more details of an ion implanter and plasma implanter that can be used to implant the ion flux into the silicon substrate.

Each of the possible platforms that can be used to implant an ion flux into the silicon substrate will have a transport mechanism for loading the substrate prior to ion implantation and removing the substrate after the implantation. In one embodiment, the transport mechanism may be a load lock that removes the silicon substrate from a loading cassette or substrate holder and introduces it into a vacuum chamber for ion implantation. In particular, the transport mechanism will place the silicon substrate in the chamber in the path of the ion flux such that the flux hits the substrate, causing the ions to penetrate the surface of the substrate and come to rest beneath the surface at a certain depth. After completing the processing of the substrate, another transport mechanism will transport the substrate from the chamber.

The ion flux can be one or more of a variety of different ions. For instance, in one embodiment the ion flux can be ions selected from the group consisting of hydrogen, helium and a combination of hydrogen and helium. Implanting a high enough dose (e.g., 1E15-2E17 cm-2) of these ions into the silicon substrate at an energy that ranges from about 20 keV to about 300 keV, while maintaining wafer temperature during ion implantation at less than 300 degrees Celsius (C.), causes the ions to penetrate a certain depth into the silicon and form bubbles. These bubbles are the media which results in a delamination of a top silicon layer from the substrate. This process has been used previously in the manufacture of silicon-on-insulators but the structure of a starting substrate for a silicon solar cell is vastly different from a silicon-on-insulator structure as are the applications (e.g., a solar cell versus a semiconductor device such as a microprocessor). For instance, silicon-on-insulator manufacturing requires transfer of a thin layer from a thick donor wafer to an oxidized substrate, whereas a solar cell substrate according to this disclosure bonds the thin-film to a non-silicon substrate and uses an epitaxial film and not an oxidized substrate.

Referring back to FIG. 1, the ion implanted silicon substrate is optionally treated at 130 to further trigger delamination of a surface layer of silicon. In one embodiment, this optional treatment may comprise mechanical (e.g., ultrasound to impose a mechanical action, polishing, etc.) or thermal treatment (e.g., anneal). Any one of these treatments will trigger delamination of a top silicon layer from the silicon substrate. In addition to triggering delamination, these treatments aid in reducing surface roughness and passivating the surface (i.e., makes the surface cleaner and more stable).

The delamination of a top silicon layer from the silicon substrate leads to the cleaving of a thin-film of silicon from the ion implanted silicon substrate at 140. In one embodiment, the cleaved thin-film of silicon has a thickness that is less than about five microns. In another embodiment, the cleaved thin-film of silicon has a thickness that ranges from about one quarter of a micron to about two microns. In yet another embodiment, the cleaved thin-film of silicon has a thickness that is less than about one micron.

The same silicon substrate from which the cleaved thin-film of silicon was taken can be used again to obtain more thin-films of ion implanted silicon. In particular, the same silicon substrate can be ion implanted with an ion flux of ions selected from the group consisting of hydrogen, helium and a combination of hydrogen and helium. Then a thin-film of silicon is again cleaved from the silicon substrate. Each subsequent cleaved thin-film of silicon can be used in a separate solar cell substrate. Thus, one silicon substrate can be used to yield significantly more solar cell substrates as compared to the current process of manufacturing solar cell substrates. In particular, in the current process, a thin wire about 200 microns to about 220 microns is used to saw a silicon ingot. The thickness of this wire results in about 200 microns to about 220 microns of silicon that is wasted as the wire slices through the silicon ingot. As mentioned above, the thickness of a solar cell substrate produced from this process will have a thickness that ranges from about 150 microns to about 270 microns. Thus, some advantages heretofore in the description of forming a solar cell substrate are that the substrates are significantly thinner than the thickness produced by using a thin wire and the yield of these substrates is substantially higher.

Referring back to FIG. 1, the thin-film of silicon once cleaved is attached to a non-silicon substrate at 150 to form a solar cell substrate. In one embodiment, the non-silicon substrate can comprise glass, ceramic, plastic, silicon nitride (SiN) on metallurgical grade silicon, capped metal grade silicon (e.g., SiN on metal). Those skilled in the art may even desire to use a transport conductive oxide (TCO) layer on the non-silicon substrate. In one embodiment, the TCO layer may be fluorine (F) or antimony doped tin oxide (Sb doped with SnO₂). Other materials such as indium tin oxide (ITO) and zinc oxide (ZnO) can be used in place of or in combination with the TCO.

The thin-film of silicon can be attached to the non-silicon substrate in one of a number of well-known approaches. In one embodiment, the attaching of the non-silicon substrate to the thin-film of silicon comprises well-known techniques of bonding or gluing.

Because it may be difficult to obtain a thin-film of silicon that has a thickness greater than one micron it may be desirable to perform post cleave processing of the solar cell substrate to obtain an increased thickness. In one embodiment, increased thickness can be obtained by growing an epitaxial film on the solar cell substrate at 160. In one embodiment, the epitaxial film can be used to increase the thickness of the solar cell substrate about one micron to about twenty microns. There are several approaches that can be used to grow the epitaxial film on the solar cell substrate. For example, in one embodiment, an epitaxial film can be grown by using an epitaxial reactor. In one embodiment, an epitaxial reactor can be used to grow the epitaxial film. In this embodiment, the epitaxial reactor uses a temperature that ranges from 600-1000 degrees C. with deposition gases such as silane, dichlorsilane, or trichlorsilane. The epitaxial film can be doped using either diborane or phosphine depending on the conductivity type of the material desired.

In another embodiment, an epitaxial film can be grown on the solar cell substrate using a well-known amorphous deposition technique that uses an amorphous silicon deposition reactor. Amorphous deposition of silicon occurs at low temperature, less than 700 degrees C., and silicon from a precursor of either silane or other number of silicon rich molecules is used. The epitaxial film obtained by amorphous deposition can be converted to a single or poly crystal using a well-known solid-phase epitaxy. Typical conditions for converting the epitaxial film to a single or poly crystal using a solid-phase epitaxy include thermal treatments in the range of 400-800 degrees C. in an inert ambient such as nitrogen (N), argon (Ar) or the like.

The solar cell substrate after post-cleave processing also constitutes a starting substrate for a solar cell fabrication that is significantly thinner than the thickness of a conventional solar cell substrate produced by using a thin wire sawing technique. In addition, the costs of manufacturing these solar cell substrates will be lower because the cost of the material will be lower and there will be a greater yield of substrates per kilogram of starting polysilicon for use in solar cell applications. Also, the resulting epitaxial silicon will be of a higher quality, higher minority carrier lifetimes due to less contaminants, resulting in improved solar conversion efficiency. The lower costs associated with fabricating these solar cell substrates make it possible to achieve a lower cost per watt compared to the conventional solar cells.

The foregoing flow chart shows some of the processing functions associated with forming a substrate for use as a solar cell. In this regard, each block represents a process act associated with performing these functions. It should also be noted that in some alternative implementations, the acts noted in the blocks may occur out of the order noted in the figure or, for example, may in fact be executed substantially concurrently or in the reverse order, depending upon the act involved. Also, one of ordinary skill in the art will recognize that additional blocks that describe the processing functions may be added

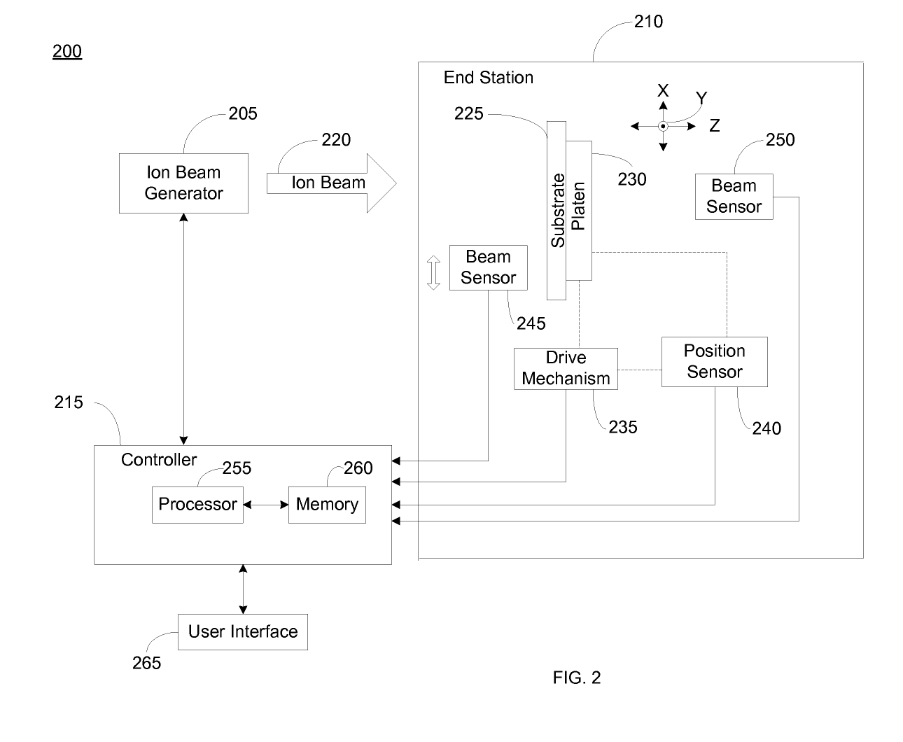

FIG. 2 shows a schematic block diagram of an ion implanter 200 used in an aspect of forming a solar cell substrate according to one embodiment of this disclosure. The ion implanter 200 includes an ion beam generator 205, an end station 210, and a controller 215. The ion beam generator 205 generates an ion beam 220 and directs it towards a front surface of a substrate 225. The ion beam 220 is distributed over the front surface of the substrate 225 by beam scanning, substrate movement, or by any combination thereof.

The ion beam generator 205 can include various types of components and systems to generate the ion beam 220 having desired characteristics. The ion beam 220 may be a spot beam or a ribbon beam. The spot beam may have an irregular cross-sectional shape that may be approximately circular in one instance. In one embodiment, the spot beam may be a fixed or stationary spot beam without a scanner. Alternatively, the spot beam may be scanned by a scanner for providing a scanned ion beam. The ribbon beam may have a large width/height aspect ratio and may be at least as wide as the substrate or multiple substrates if multiple substrates are to be processed simultaneously. The ion beam 220 can be any type of charged particle beam such as an energetic ion beam used to implant the substrate 225.

The end station 210 may support one or more substrates in the path of the ion beam 220 such that ions of the desired species are implanted into the substrate 225. The substrate 225 may be supported by a platen 230.

The end station 210 may include a drive system (not illustrated) that physically moves the substrate 225 to and from the platen 230 from holding areas. The end station 210 may also include a drive mechanism 235 that drives the platen 230 and hence the substrate 225 in a desired way. The drive mechanism 235 may include servo drive motors, screw drive mechanisms, mechanical linkages, and any other components as are known in the art to drive the substrate 225 when clamped to the platen 230.

The end station 210 may also include a position sensor 240, which may be further coupled to the drive mechanism 235, to provide a sensor signal representative of the position of the substrate 225 relative to the ion beam 220. Although illustrated as a separate component, the position sensor 240 may be part of other systems such as the drive mechanism 235. Furthermore, the position sensor 240 may be any type of position sensor known in the art such as a position-encoding device. The position signal from the position sensor 240 may be provided to the controller 215.

The end station 210 may also include various beam sensors to sense the beam current density of the ion beam at various locations such as a beam sensor 245 upstream from the substrate 225 and a beam sensor 250 downstream from the substrate. As used herein, “upstream” and “downstream” are referenced in the direction of ion beam transport or the Z direction as defined by the X-Y-Z coordinate system of FIG. 2. Each beam sensor 245, 250 may contain a plurality of beam current sensors such as Faraday cups arranged to sense a beam current density distribution in a particular direction. The beam sensors 245, 250 may be driven in the X direction and placed in the beam line as needed.

Those skilled in the art will recognize that the ion implanter 200 may have additional components not shown in FIG. 2. For example, upstream of the substrate 225 there may be an extraction electrode that receives the ion beam from the ion beam generator 205 and accelerates the positively charged ions that form the beam, an analyzer magnet that receives the ion beam after positively charged ions have been extracted from the ion beam generator and accelerates and filters unwanted species from the beam, a mass slit that further limits the selection of species from the beam, electrostatic lenses that shape and focus the ion beam, and deceleration stages to manipulate the energy of the ion beam. Within the end station 210 it is possible that there are other sensors such as a beam angle sensor, charging sensor, position sensor, temperature sensor, local gas pressure sensor, residual gas analyzer (RGA), optical emission spectroscopy (OES), ionized species sensors such as a time of flight (TOF) sensor that may measure respective parameters.

The controller 215 may receive input data and instructions from any variety of systems and components of the ion implanter 200 and provide output signals to control the components of the implanter. The controller 215 can be or include a general-purpose computer or network of general-purpose computers that may be programmed to perform desired input/output functions. The controller 215 may include a processor 255 and memory 260. The processor 255 may include one or more processors known in the art. Memory 260 may include one or more computer-readable medium providing program code or computer instructions for use by or in connection with a computer system or any instruction execution system. For the purposes of this description, a computer readable medium can be any apparatus that can contain, store, communicate, propagate, or transport the program for use by or in connection with the computer, instruction execution system, apparatus, or device. The computer-readable medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include a compact disk-read only memory (CD-ROM), a compact disk-read/write (CD-R/W) and a digital video disc (DVD).

The controller 215 can also include other electronic circuitry or components, such as application specific integrated circuits, other hardwired or programmable electronic devices, discrete element circuits, etc. The controller 215 may also include communication devices.

A user interface system 265 may include, but not be limited to, devices such as touch screens, keyboards, user pointing devices, displays, printers, etc., that allow a user to input commands, data and/or monitor the ion implanter 200 via the controller 215.

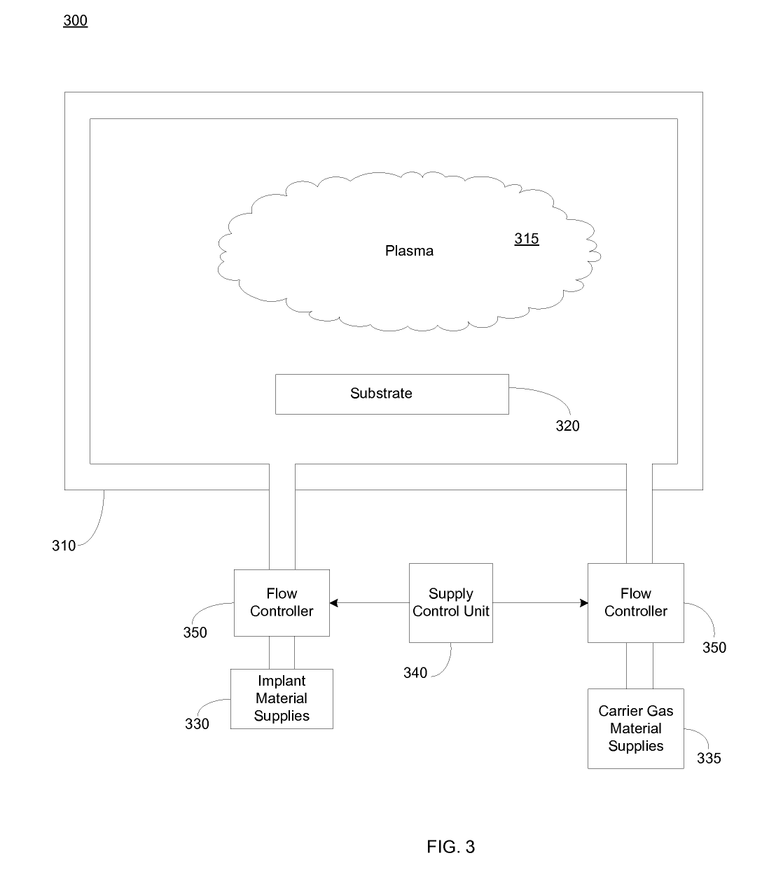

FIG. 3 shows a schematic block diagram of a plasma implanter 300 used in an aspect of forming a solar cell substrate according to one embodiment of this disclosure. The plasma implanter 300 includes a vessel 310 associated with a chamber that can contain a plasma 315 and one or more substrates 320, which can be exposed to the plasma. The plasma implanter 300 also includes one or more implant material supplies 330, one or more carrier gas material supplies 335, flow controllers 350, and one or more supply control units 340. It also includes high voltage (10-120 KV) DC or pulsed power supply enabling acceleration of extracted ions prior to reaching surface of the implanted substrate.

The supplies 330, 335 supply materials to the vessel 310 for formation and maintenance of a plasma. The flow controllers 350 regulate the flow of materials from the supplies 330, 335 to control, for example, the pressure of gaseous material delivered to the vessel 310. The supply control unit 340 is configured to control, for example, a mixture of carrier gas supplied to the vessel 310 by communicating with the flow controllers 350. The material supplies 330, 335, flow controllers 350, and control units 340 can be of any suitable kind, including those known to one having ordinary skill in the plasma implant arts.

In one mode of operation, the plasma implanter 300 utilizes a pulsed plasma. A substrate 320 is placed on a conductive platen that functions as a cathode, and is located in the vessel 310. An ionizable gas containing, for example, an implant material, is introduced into the chamber, and a voltage pulse is applied between the platen and an anode to extract ions from plasma generated by an external source, such as an RF plasma generator or from a self-ignited glow discharge. An applied voltage pulse can cause ions in the plasma to cross the plasma sheath and to be implanted into the substrate. A voltage applied between the substrate and the anode can be used to control the depth of implantation. The voltage can be ramped in a process to achieve a desirable depth profile. With a constant doping voltage, the implant will have a tight depth profile. With a modulation of doping voltage, e.g., a ramp of doping voltage, the implant can be distributed throughput the thin-film, and can provide effective passivation to defect sites at variable depths.

The use of an ion implanter and a plasma implanter is beneficial in cleaving the thin-film of silicon from the silicon substrate because of the unique control features that the ion implanter and plasma implanter provide. In particular, use of an ion implanter and a plasma implanter enables a precise adjustment of dopant level, dopant depth profile by ion dosage, ion energy and angular control if necessary; that all can be used to obtain the desired cleaving effect for desired levels of thickness.

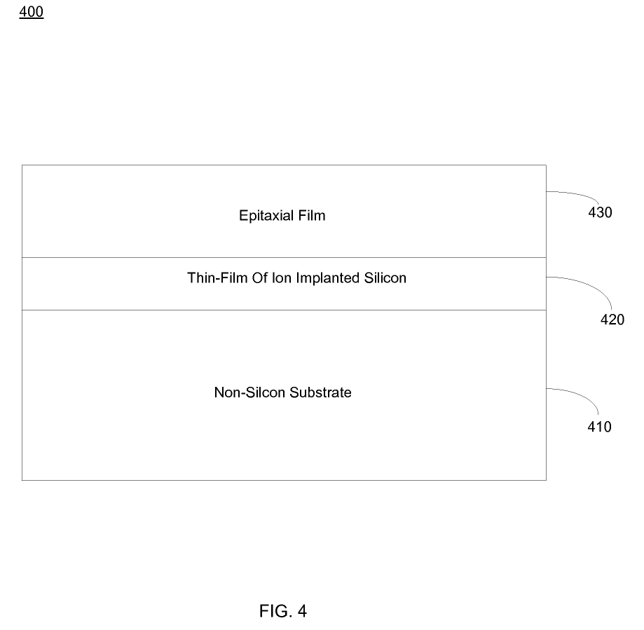

FIG. 4 is a cross-sectional schematic diagram of a solar cell substrate 400 fabricated according to one embodiment of this disclosure. The solar cell substrate 400 includes a non-silicon substrate 410. As mentioned above, the non-silicon substrate 410 can be any inexpensive and flexible type of non-silicon substrate such as glass, ceramic, plastic, SiN on metallurgical grade silicon, or capped metal grade silicon (e.g., SiN on metal) that can withstand high temperature operations without degrading the electrical properties (resistivity, minority carrier lifetime, etc.) of the cleaved silicon. Another feature of the non-silicon substrate 410 is that it serves as a diffusion barrier that prevents the diffusion of contaminants into the good quality (high minority carrier lifetime) epitaxial layer which is impurity and defect free. Basically, substrate 410 is any non-silicon material that costs significantly less than semi-grade silicon and has a similar coefficient of thermal expansion as silicon.

FIG. 4 further shows that a thin-film of ion implanted silicon 420 is attached to the non-silicon substrate 410. As mentioned above, the thin-film of ion implanted silicon 420 has a thickness that is less than about five microns with a preferred range of about one quarter of a micron to about two microns and more preferably a range that is less than about one micron. Also, as mentioned above, the thin-film of ion implanted silicon 420 can be attached to the non-silicon substrate 410 by well-known techniques such as bonding or gluing.

The solar cell substrate 400 as shown in FIG. 4 further includes an epitaxial film 430 grown on the thin-film of ion implanted silicon 420. In one embodiment, the epitaxial film 430 has a thickness that ranges from about one micron to about twenty microns. The solar cell substrate 400 shown in FIG. 4 can be fabricated in the manner described with reference to FIG. 1. In particular, the solar cell substrate 400 can be fabricated by using ion implantation, cleaving, attaching techniques, epitaxial film growth and the other aforementioned processing acts.

It is apparent that there has been provided with this disclosure an approach for nano-cleaving a thin-film of silicon for solar cell fabrication. While the disclosure has been particularly shown and described in conjunction with a preferred embodiment thereof, it will be appreciated that variations and modifications will occur to those skilled in the art. Therefore, it is to be understood that the appended claims are intended to cover all such modifications and changes as fall within the true spirit of the invention.

1. A method of forming a substrate for use as a solar cell substrate, comprising:
providing a substrate of silicon;
implanting the silicon substrate with an ion flux;
cleaving a thin-film of silicon from the ion implanted silicon substrate; and
attaching a non-silicon substrate to the thin-film of silicon to form a solar cell substrate.

2. The method according to claim 1, wherein the substrate of silicon comprises monocrystalline silicon or polycrystalline silicon.

3. The method according to claim 1, wherein the ion flux comprises ions selected from the group consisting of hydrogen, helium and a combination of hydrogen and helium.

4. The method according to claim 1, wherein the implanting comprises using a ion implanter.

5. The method according to claim 1, wherein the implanting comprises using a plasma implanter.

6. The method according to claim 1, wherein the cleaved thin-film of silicon has a thickness that is less than about five microns.

7. The method according to claim 6, wherein the cleaved thin-film of silicon has a thickness that ranges from about one quarter of a micron to about two microns.

8. The method according to claim 6, wherein the cleaved thin-film of silicon has a thickness that is less than about one micron.

9. The method according to claim 1, wherein the attaching of the non-silicon substrate to the thin-film of silicon comprises bonding or gluing.

10. The method according to claim 1, further comprising growing an epitaxial film on the solar cell substrate.

11. The method according to claim 10, wherein the growing of the epitaxial silicon film comprises using an amorphous silicon deposition reactor.

12. The method according to claim 11, further comprising converting the epitaxial silicon film to a single or poly crystal.

13. The method according to claim 12, wherein the converting of the epitaxial silicon film comprises using a solid-phase epitaxy.

14. The method according to claim 10, wherein the growing of the epitaxial film comprises increasing the thickness of the solar cell substrate from about one micron to about twenty microns.

15. The method according to claim 1, further comprising treating the cleaved thin-film of silicon.

16. The method according to claim 15, wherein the treating comprises a mechanical or thermal treatment.

17. A method of forming a substrate for use as a solar cell substrate, comprising:
providing a substrate of silicon;
implanting the silicon substrate with an ion flux;
cleaving a thin-film of silicon from the ion implanted silicon substrate;
attaching a non-silicon substrate to the thin-film of silicon to form a solar cell substrate; and
post cleave processing of the solar cell substrate.

18. The method according to claim 17, wherein the post cleave processing comprises growing an epitaxial film on the solar cell substrate.

19. The method according to claim 18, wherein the growing of an epitaxial silicon film comprises using an amorphous silicon deposition reactor.

20. The method according to claim 19, further comprising converting the epitaxial silicon film to a single or poly crystal.

21. The method according to claim 20, wherein the converting of the epitaxial silicon film comprises using a solid-phase epitaxy.

22. The method according to claim 18, wherein the growing of the epitaxial film comprises increasing the thickness of the solar cell substrate from about one micron to about twenty microns.

23. A solar cell substrate, comprising:
a thin-film of ion implanted silicon, wherein the thin-film of ion implanted silicon has a thickness that is less than about five microns; and
a non-silicon substrate attached to the thin-film of ion implanted silicon.

24. The solar cell substrate according to claim 23, further comprising an epitaxial film grown on the thin-film of ion implanted silicon, wherein the epitaxial film has a thickness that ranges from about one micron to about twenty microns.

25. A system for forming a solar cell substrate, comprising:
means for providing a substrate of silicon;
means for implanting the silicon substrate with an ion flux;
means for cleaving a thin-film of silicon from the ion implanted silicon substrate; and
means for attaching a non-silicon substrate to the thin-film of silicon to form a solar cell substrate.
